(19) United States
(12) Patent Application Publication
(10) Pub. No.: US 2010/0224890 A1
(43) Pub. Date: Sep. 9, 2010

(54) Light emitting diode chip with electrical insulation element

(75) Inventors: Bernd Keller, Santa Barbara, CA (US); Ashay Chitnis, Goleta, CA (US); James Ibbetson, Santa Barbara, CA (US)

Correspondence Address: KOPPEL, PATRICK, HEYBL & DAWSON, 2815 Townsgate Road, SUITE 215, Westlake Village, CA, 91361-5827, US

(73) Assignee: CREE, INC.

(21) Appl. No.: 11/523,381

(22) Filed: Sep. 18, 2006

(51) Int. Cl. H01L 33/64; H01L 33/48; H01L 21/58; H01L 33/02

(52) U.S. Cl. 257/93; 257/99; 438/122; 438/26; 257/E33.005; 257/E33.056; 257/E33.075; 257/E21.505

(57) ABSTRACT

A light emitting diode chip comprising a light emitting diode and a thermally conductive substrate. The light emitting diode is on the substrate with the substrate providing a thermal path from the light emitting diode through the substrate. A mounting pad is also on a substrate and an electrically insulating layer is integral to the substrate. The insulating layer electrically insulates the mounting pad from the light emitting diode. A method for fabricating a light emitting diode chip comprises providing a thermally conductive substrate, forming an electrical insulating layer integral to the substrate and forming a mounting pad on the substrate. A light emitting diode is fabricated and mounted to the substrate, with the light emitting diode electrically insulated from the mounting pad by the electrically insulating layer.

This invention was made with Government support under government contact Department of Commerce 70NANB4H3037. The Government has certain rights in this invention

### BACKGROUND OF THE INVENTION

1. Field of the Invention

This invention relates to light emitting diodes and in particular to light emitting diodes having thermally conductive substrates and electrically neutral bonding pads.

2. Description of the Related Art

Light emitting diodes (LED or LEDs) are solid state devices that convert electric energy to light and generally comprise an active region of semiconductor material sandwiched between two oppositely doped layers of semiconductor material. When a bias is applied across the doped layers, holes and electrons are injected into the active region where they recombine to generate light. Light is emitted from the active layer and from all surfaces of the LED. Recent advances in LEDs (such as nitride based LEDs) have resulted in highly efficient light sources that surpass the efficiency of filament based light sources while providing a light with equal or greater brightness in relation to its input power.

Solid state lighting (SSL) packages have been developed having a plurality of LED chips mounted to a package, circuit board, or a heat sink. When a bias is applied to each of the LEDs the SSL package emits the combined light from the LED chips. Some standard LED chips can be fabricated on either thermally or electrically conductive substrates. Electrically conductive substrates typically result in an LED with an active backside mounting pad (metal) and this arrangement is particularly applicable to vertical geometry LED chips. In these embodiments, a bias can be applied to the LEDs through the active backside metal, and through an LED chip contact. In some SSL packages it is desirable to individually control the emission of the LED chips in the package. Individual control using vertical geometry LED chips with active backside mounting pads can require complicated package, circuit board and heat sink design.

Some SSL packages utilize LED chips having high light output characteristics, which results in elevated LED chip operating temperatures. In these SSL packages the LED chips should have low thermal resistance from the heat generating junction of the LED to the SSL package, circuit board and heat sink that allow heat from the LED to conduct away from the LED where it can dissipate. To allow for individual control of the LEDs, it may be desirable for the LED chips to have a mounting option that allows for thermal bonding to the circuit board with a solderable electrically neutral thermal pad that is not used for applying a bias to the LED chip.

Flip-chip LEDs minimize thermal resistance to the package, circuit board and heat sink, but create an electrically active thermal pad below the chip. In other SSL packages, an electrically neutral thermal pad can be created by incorporating a dielectric into the SSL package (e.g. alumina substrates). This, however, substantially increases the packages thermal resistance reducing the LED chip's ability to conduct heat away from the LEDs. Electrically neutral pads can also be created with LEDs grown on electrically insulating substrates, such as sapphire. These types of substrates, however, typically suffer from poor thermal conductivity. For example sapphire can have thermal conductivity of 35 w/mK compared to 148 w/mK for silicon (Si) or 350 W/mK for silicon carbide (SiC).

### SUMMARY OF THE INVENTION

Briefly and in general terms the present invention relates to semiconductor devices and in particular LEDs, arranged on thermally conductive substrates having an electrically neutral bonding/mounting pad. One embodiment of a light emitting diode chip according to the present invention comprises a thermally conductive substrate with a light emitting diode mounted on the substrate. The substrate provides a thermal path to draw heat away from the light emitting diode. A mounting pad is included on the substrate, said mounting pad electrically insulated from the light emitting diode through the substrate.

Another embodiment of a light emitting diode chip according to the present invention comprises a light emitting diode and a thermally conductive substrate. The emitting diode is on the substrate with the substrate providing a thermal path from the light emitting diode through the substrate. A mounting pad is on the substrate and an electrically insulating layer is integral to the substrate. The insulating layer electrically insulates the mounting pad from the light emitting diode.

One embodiment of a semiconductor device chip, comprising a semiconductor device comprising a plurality of semiconductor layers, and a thermally conductive substrate. The device is on the substrate with the substrate providing a thermal path from the device through the substrate. A mounting pad on the substrate for mounting the substrate. An electrically insulating layer is integral to the substrate and electrically insulating the mounting pad from the device.

One embodiment of a solid state light according to the present invention comprises a light emitting diode chip having a thermally conductive substrate and a light emitting diode mounted on the substrate. The substrate provides a thermal path to draw heat away from the light emitting diode. A mounting pad is on the substrate for mounting said light emitting diode and the bonding pad is electrically insulated from said light emitting diode throught the substrate. A circuit board is included with the light emitting diode chip mounted to said circuit board by the mounting pad.

One embodiment of a method for forming a semiconductor device chip according to the present invention comprises providing a thermally conductive substrate and forming an electrical insulating layer integral to the substrate. A mounting pad is also formed on said substrate. A semiconductor device is fabricated having a plurality of semiconductor layers and the semiconductor device is mounted to the substrate. The substrate provides a thermal path from the semiconductor device through the substrate. The insulating layer electrically is formed to insulate the semiconductor device from the mounting pad.

One method for fabricating a light emitting diode chip according to the present invention comprises providing a thermally conductive substrate, forming an electrical insulating layer integral to the substrate and forming a mounting pad on the substrate. A light emitting diode is fabricated and mounted to the substrate, with the light emitting diode electrically insulated from the mounting pad by the electrically insulating layer.

These and other aspects and advantages of the invention will become apparent from the following detailed description and the accompanying drawings which illustrate by way of example the features of the invention.

### BRIEF DESCRIPTION OF THE DRAWINGS

FIG. 1 is a sectional view of one embodiment of a light emitting diode (LED) chip according to the present invention having a thermally conductive substrate and electrically neutral mounting pad;

FIG. 2 is a sectional view of another LED chip according to the present invention;

FIG. 3. is a sectional view of another embodiment of an LED chip according to the present invention having a p-type metal layer;

FIG. 4 is a sectional view of another embodiment of an LED chip according to the present invention having a wafer bond metal;

FIG. 5 is a sectional view of another embodiment of an LED chip according to the present invention also having a wafer bond metal;

FIG. 6 is a sectional view of another embodiment of an LED chip according to the present invention comprising a thermally conductive dielectric substrate;

FIG. 7 is a sectional view of another embodiment of an LED chip according to the present invention comprising a light extraction elements;

FIG. 8 is a perspective view of one embodiment of an solid state light (SSL) according to the present invention;

FIG. 9 is a flow diagram for one embodiment of a method for fabricating a semiconductor chip according to the present invention; and

FIG. 10 is flow diagram for one embodiment of a method for fabricating a semiconductor chip according to the present invention.

### DETAILED DESCRIPTION OF THE INVENTION

The present invention generally relates to LED chips and solid state lights (SSL) utilizing the LED chips, although the invention herein can be used with other semiconductor devices. The present invention is particularly applicable to horizontal geometry LEDs comprising an LED arranged on a substrate having thermally conductive characteristics. According to the present invention, the LED chips also comprise an electrically neutral backside mounting/bonding pad (metal). To provide the electrically neutral mounting pad, the substrates can incorporate a layer of electrically insulating material at the LED chip level, with a suitable material being a dielectric. The insulating layer can be thermally grown or deposited material such as Si₃N₄, SiO₂, Si(NO)x or similar materials integral to the LED chip. In one embodiment, an integral insulating layer can be included in wafer bonded LEDs chips by bonding the LED to wafers that have the insulator already grown/deposited on it. In other embodiments the LED can be fabricated on semi-insulating substrates that provide good thermal conductivity and also provide an electrically neutral mounting pad.

Integrating an electrically insulating layer at the chip level allows for superior control of the thickness of the insulating layer and allows for the layer as low as 0.1 to 5 micrometers (μm). Insulating layers in this range of thicknesses do not significantly impact thermal conductivity of the LED chip and in particular the ability of heat to transmit from the LED through the thermally conductive substrate. LED chips according to the present invention achieve a combination of the desired thermal conductivity through the substrate and an electrically neutral mounting pad. LED chips according to the present invention can be mounted in SSL packages having different types of circuit board, including metal core circuit boards or circuit boards with thermal vias. The LED chips can then be individually controlled by providing conductors, such as wire bonds, to each of the LED chips.

It will be understood that when an element or layer is referred to as being “on”, “connected to”, “coupled to”, “in contact with” another element or layer or “between” elements or layers, it can be directly on, connected or coupled to, in contact with or between the other elements or layers or intervening elements or layers may be present. In contrast, when an element is referred to as being “directly on,” “directly connected to”, “directly coupled to”, “directly in contact with” or “directly between” another element or layer, there are no intervening elements or layers present. Likewise, when a first element or layer is referred to as being “in electrical contact with” or “electrically coupled to” a second element or layer, there is an electrical path that permits current flow between the first element or layer and the second element or layer. The electrical path may include capacitors, coupled inductors, and/or other elements that permit current flow even without direct contact between conductive elements.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section.

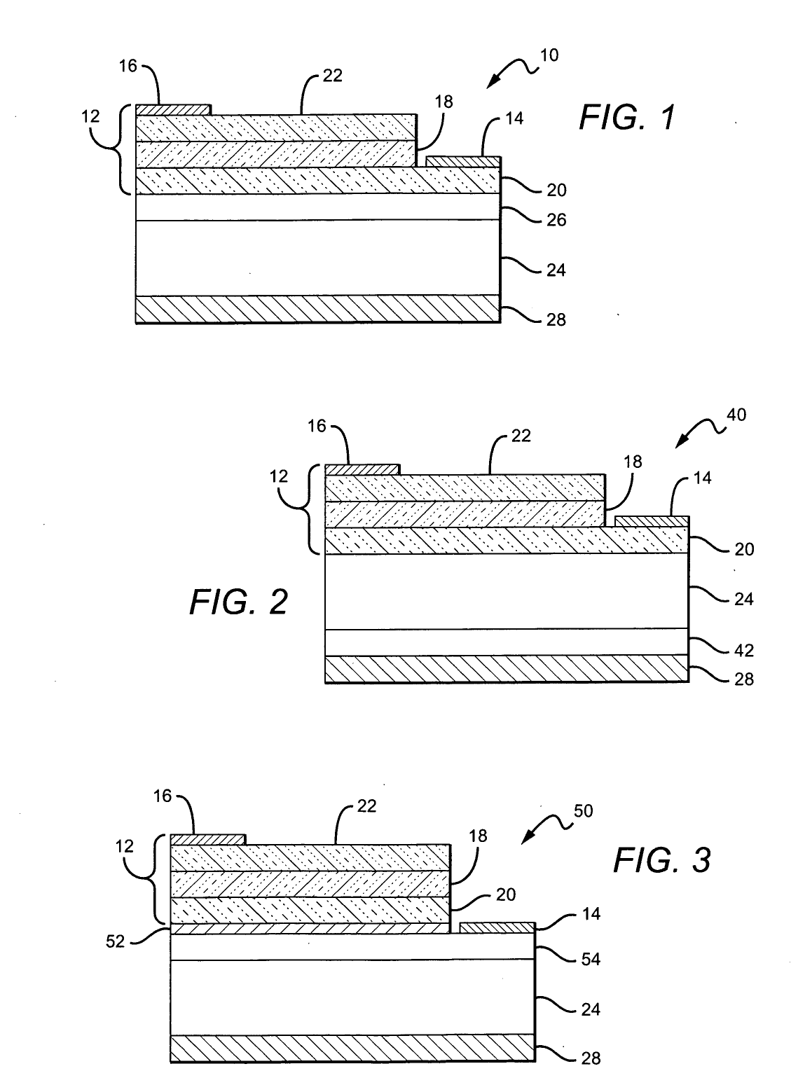

FIG. 1 shows one embodiment of semiconductor chip 10 according to the present invention comprising an active semiconductor device 12 having a plurality of semiconductor layers. The device 12 can comprise many different components such as diodes or transistors, or lighting devices such as LEDs or solid state lasers. The different devices can also have different numbers of bond pads and different devices can include different numbers of layers.

In one embodiment of the present invention the device 12 comprises a light emitting diode (LED). The LED chip 10 embodiment shown in FIG. 1 and the embodiments below, are described herein with the device 12 being an LED. It is understood that this is simply one example of the devices that can be used according to the present invention, and should not be limiting.

LEDs are relatively well known in the art and are only discussed briefly herein. The semiconductor layers of an LED generally comprise an active region 18 that can have many different structures such as single quantum well (SQW) or multiple quantum well (MQW). The active region 18 is sandwiched between first and second doped layers 20, 22. First and second bond pads 14, 16 are provided, with the first bond pad 14 in ohmic contact with the first doped layer 20 and the second bond pad in ohmic contact with the second doped layer 22. The layers 20, 22 are oppositely doped, with one being p-type doped and the other being n-type doped. In the LED chip 10 embodiment, first layer 20 is n-doped and the second layer is p-type, with current from the first bond pad 14 spreading through the layer 20. The LED chip 10 can include one or more contact layers (not shown), which can comprise metal or other conductive materials. In particular, a contact layer can be included on the second (p-type) doped layer 22 to assist in current spreading from the second bond pad 16.

As mentioned, the present invention is particularly applicable to horizontal geometry LEDs, with the LED 10 illustrating this type of geometry. The LED's oppositely doped layers 20, 22 are contacted from the top through bond pads 14, 16. This typically requires removal a portion of the region 18, and layers 20 and 22 to allow access for the bond pad 16. This removal can be accomplished using known methods, with a suitable method being etching.

The region 18 and layers 20, 22 can be made from many different semiconductor materials but are preferably made of a Group-III nitride material. Group III nitrides refer to those semiconductor compounds formed between nitrogen and the elements in the Group III of the periodic table, usually aluminum (Al), gallium (Ga), and indium (In). The term also refers to ternary and tertiary compounds such as AlGaN and AlInGaN. In a preferred embodiment, the material forming the region 18 and layers 20, 22 is AlGaN/Gan, although in other embodiments it can be AlGaAs or AlGaInP, as well as other materials.

The details of operation and fabrication of conventional LEDs are also generally known in the art and are only briefly discussed. Conventional LEDs can be fabricated by known methods, with a suitable method being fabrication by Metal Organic Chemical Vapor Deposition (MOCVD). In operation, conductors can be connected to the bond pads 14, 16 and an electrical signal supplied on the conductors (wire bonds) can be applied across the bond pads 14, 16. This signal is spread through the layers 20, 22, causing the active region 18 to emit light.

The LED chip 10 further comprises a substrate 24 that is preferably thermally conductive to allow heat to conduct away from the LED through the substrate 24 during operation. The substrate 24 also provides mechanical stability for the LED 12. Many different materials can be used for the substrate 24, including but not limited to silicon (Si), silicon carbide (SiC), or metals such as copper or gold. The LED 12 can be bonded to the substrate 24 using many different mounting methods, with a suitable method being wafer bonding as described in more detail below.

The chip 10 further comprises an integral electrically insulating layer 26 that allows for the LED chip 10 to also have an electrically neutral mounting pad. That is, when the mounting pad is used for mounting the chip 10 to a structure, such as an SSL package circuit board or heat sink, the LED 12 is electrically insulated from the structure by the insulating layer 26. The insulating layer 26 blocks the electrical path between the structure and LED 12. In the chip 10, the insulating layer 26 is arranged on the “topside” of the substrate and covers the top surface of the substrate 24. With the LED 12 mounted in place, the insulating layer is preferably sandwiched between the LED 12 and substrate 24. In other embodiments the insulating layer can be in other locations and can cover less than all of the substrate 24.

The insulating layer 26 can be made of many different materials, with a suitable material being a dielectric such as an oxide or nitride. The insulating layer 26 can be grown or sputtered on the substrate 24 prior to the LED 12 being mounted on the substrate 24. In other embodiments the layer 26 can be grown or sputtered on the LED 12 prior to it being mounted to the substrate 24. Many alternative materials can be used for the insulating layer 26 including but not limited to dielectric polymers, spin-on glasses, spin-on glass-polymer composite materials, insulating epoxies or other insulating bonding agents or adhesives. Arranging the insulating layer 26 at the top of substrate 26 allows for wafer thinning after completion of the wafer bonding. This arrangement also allows for use of high thermal dielectric fabrication methods for the insulating layer, such as formation by wet or dry thermal oxide growth at temperatures up to 1000° C. The resulting insulating layer 26 comprises a strong and dense dielectric that can be thin and remain electrically insulating.

In some embodiments the insulating layer 26 can be made of a material having low thermal conductivity characteristics. In these embodiments the layer 26 is fabricated with a thickness tailored to minimize interruption of the thermal path from the LED 12 through the substrate 24. This allows the chip 10 to maintain its heat spreading properties while remaining electrically neutral through the substrate 24. The thickness of the layer 26 can be accurately controlled to the desired thickness, with suitable layers being in the range of 0.1 to 5 micrometers thick. It is understood, however, that the layer 26 can have thicknesses outside this range.

The chip 10 can also comprise a solderable backside metal or mounting pad 28 for mounting the LED chip 10 using known mounting processes. The mounting pad is preferably on a surface of the substrate 24 opposite the LED 12, but can be in other locations in embodiments where the insulating layer 26 is arranged differently. The insulating layer 26 blocks electric flow through the substrate 24 and also blocks electric flow from the mounting pad 28 to the LED 12. Accordingly, the mounting pad is considered electrically neutral in that it is electrically insulated from the LED 12. The LED chip 10 can be mounted to a structure such as a circuit board or heat sink by its mounting pad using known soldering methods, and the LED 12 will be electrically insulated from the structure. The LED chip 10 can be mounted to a circuit board or heat sink and operated as a single emitting device. Alternatively, the chip 10 can be mounted with other chips in an array to circuit board, heat sink, or submount, to form a solid state light (SSL). In both these arrangements, the electrically neutral substrate allows the LED chips to be individually controlled. Electrical signals are applied to the LED 12 through the bond pads 14, 16, not through the substrate. This allows for individual control of each of the chips 10 with reduced complexity. Each of the chips 10 also retains its thermal path through the substrate 24 for efficient heat spreading from the LED 12. This allows for each of the LEDs 12 to operate at elevated temperatures.

LEDs 12 are typically fabricated on a substrate, and many different growth substrates can be used. For Group-III nitride and other materials, silicon carbide substrates can be used such as those manufactured and sold by Cree, Inc. of Durham, N.C. Substrates can have inherent absorption characteristics and an index of refraction different from the LED's semiconductor region 18 and layers 20, 22, which can cause an increase in total internal reflection (TIR) of the light generated by the active region. These characteristics can cause reduced emission efficiency of the LED 12. The LED 12 is shown with its growth substrate removed, which can improve light extraction. The LED 12 is then mounted to substrate 24 without its growth substrate or the growth substrate is removed after mounting to the substrate 24. In either case, the resulting LED chip 10 provides an LED 12 without its growth substrate. It is understood, however, that in other embodiments of the LED chip 10, the LED can be mounted to the substrate 24 with its growth substrate and the growth substrate can remain. In these embodiments the LED is preferably flip-chip mounted on the substrate 24.

FIG. 2 shows another embodiment of an LED chip 40 according to the present invention that is similar to the LED chip 10 in FIG. 1. For those features and components in FIG. 2 (and the figures described below) that are similar to those in FIG. 1, the same reference numbers are used herein with the understanding that the description of those reference numbers in FIG. 1 applies to the reference number in this embodiment. LED chip 40 comprises an LED 12 having and active region 18 sandwiched between first and second oppositely doped layers 20, 22, with the first and second bond pads 14, 16 each of which is in ohmic contact with a respective one of the layers 20, 22. As above, the first layer 20 can be n-type doped and the second layer 22 can be p-type doped, and a contact layer (not shown) can be included on layer 22 to assist in current spreading.

The LED 40 also comprises a substrate 24 that is preferably thermally conductive to allow heat to conduct away from the LED during operation, with the substrate also providing mechanical stability for the LED 12. A solderable backside metal 28 is also included as the bottom layer.

The LED chip 40 further comprises an electrically insulating layer 42 integral to the LED chip 40 that can be made of the same materials and same thicknesses as layer 26 in FIG. 1. Insulating layer 42, however, is not on the topside of the substrate 24, but is instead on the backside or bottom surface of the substrate 24, between the substrate and the solderable mounting pad 28. This location of the insulating layer 42 also results in an electrically neutral path through the substrate 24 and an electrically neutral mounting pad 28. The insulating layer is also thin enough or made of a material that does not substantially interfere with the thermal path from the LED 12, through the substrate 24.

The insulating layers 26 and 42 have been shown as arranged on the topside and backside of the substrate 24. It is understood, however, that the insulating layers according to the present invention can be in many different locations, such as on other surfaces of the substrate or embedded in the substrate, and more than one insulating layer can be provided. Still other embodiments can comprise more than one substrate with one or more insulating layers on the surfaces of the substrates or between the substrates.

FIG. 3 shows another embodiment of an LED chip 50 also comprising an LED 12 with an active region 18 sandwiched between oppositely doped first and second layers 20, 22, with first and second bond pads 14, 16. A thermally conductive substrate 24 is also included, with the LED 12 mounted on the substrate. In this embodiment, however, the first doped layer is p-type and is particularly applicable to flip-ship mounted LEDs 12. To assist in current spreading to the p-type doped layer 20, a p-contact metal layer 52 is included between the LED 12 and the substrate 24, and in electrical contact with the first bond pad 14. A electrical signal applied to the first bond pad 14 spreads into the metal layer 52 to assist in current spreading into the p-type layer 20. A solderable mounting pad 28 is also included on the bottom surface of the substrate 24.

The LED 50 also comprises an insulating layer 54 that is similar to the insulating layer 26 in FIG. 1 and is arranged on the topside surface of the substrate 24. The insulating layer 54 provides electrical for the mounting pad while maintaining the substrates thermally conductive path. It is understood that the insulating layer 54 can be arranged in other locations integral to the LED 50, such as at the bottom surface of the substrate 24, between the substrate 24 and the mounting pad 28.

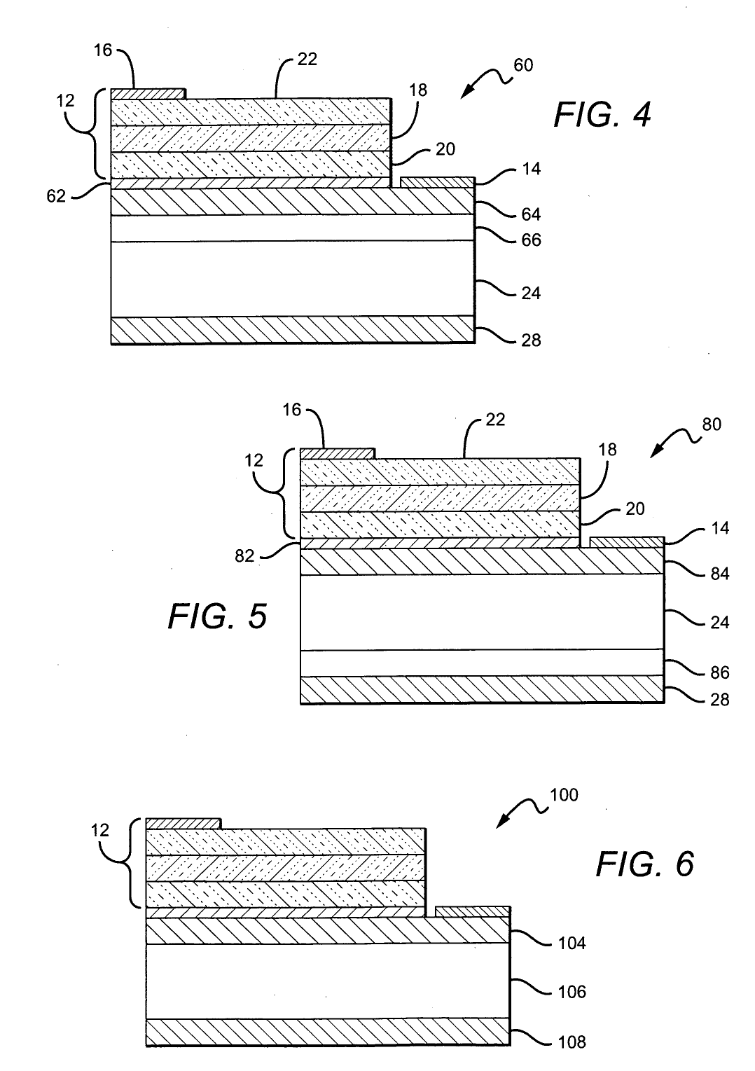

FIG. 4 shows another embodiment of an LED chip 60 according to the present invention also having an LED 12 with an active region 18 sandwiched between first and second oppositely doped layers 20, 22. It further comprises first and second bond pads 14, 16, substrate 24, and solderable mounting pad 28. In this embodiment the first doped layer is p-type doped and similar to LED chip 50 in FIG. 3, a p-type metal layer 62 is arranged between LED 12 and the substrate 24. The p-type metal layer 62 can be made of reflective material, or a conductive reflective layer can be included on the p-type metal layer 62. By being reflective, light from the LED 12 that emits toward the substrate 24 is reflected back to contribute to useful LED chip emission.

The LED chip 60 further comprises wafer bonding layer 64 that is included for wafer bonding of the LED 12 to the insulating layer 66 or the substrate 24, depending on the particular embodiment and location of the insulating layer 66. Wafer bonding is generally known in the art, and is only discussed briefly herein. The wafer bonding layer 64 serves as an intermediate layer to hold the LED chip to the substrate and/or insulating layer 66. The wafer bonding layer 64 can be made of many different materials, such as a metal, solder, or metal eutectic. These materials are thermally conductive and allow for the heat path to remain from the LED 12 through the substrate 24. In other embodiments, other intermediate layers can be used such as polymers, low melting temperature glass, and thermocompression using soft metal thin films arranged to not substantially interfere with the heat path from the LED through the substrate 24.

Wafer bonding can occur at different points in the LED chip manufacturing process according to the present invention. In one embodiment, wafer bonding can be employed to bond full wafers having a plurality of LEDs to a full wafer comprising a plurality of substrates 24 with an insulating layer 66. The individual devices can then be separated using standard process such as dicing processes. In other embodiments, the wafer bonding can occur after the LEDs are separated, with the LED bonded to a substrate wafer or a separated portion of the substrate and its insulating layer. It is also understood that other known wafer bonding processes can be used such as direct bonding, anodic bonding and dielectric to dielectric anodic bonding.

The chip 60 further comprises a topside insulating layer 66 arranged between the substrate 24 and wafer bond metal that is similar to the insulating layer 26 in FIG. 1. It is preferably made of a dielectric material that allows for the mounting pad 28 to remain electrically neutral, while also not interfering with the thermal path through the substrate.

FIG. 5 shows another embodiment of an LED chip 80 according to the present invention that is arranged similar to LED 60 in FIG. 4, comprises an LED 12 with an active region 18 sandwiched between first and second oppositely doped layers 20, 22. It further comprises first and second bond pads 14, 16, substrate 24, solderable mounting pad 28 The LED chip also comprise a p-type metal layer 82 and wafer bonding layer 84. The LED chip 80 also comprises an electrically insulating layer 86 that is arranged on the backside of the substrate 24 similar to the insulating layer 42 in the LED chip 40 of FIG. 2. The insulating layer 86 can be made of the same materials and is arranged to provide electrical neutrality for the mounting pad 28 while not substantially interfering with the thermal path through the substrate 24.

Other materials can be used and components can be included in the LED chip to provide a thermally conductive substrate that allows for an electrically neutral mounting pad. FIG. 6 shows another embodiment of an LED chip 100 according to the present invention having LED 12, mounted on a substrate 104 by wafer bonding by the wafer bond layer 106. The substrate 104 also has a mounting pad 108 opposite the LED 12. The substrate 104, however, does not include a insulating layer to provide electrical neutrality for the mounting pad 108. Instead, the substrate 104 can be made of thermally conductive dielectric materials including but not limited to semi-insulating silicon carbide (Si-SiC), semi-insulating silicon (SI-silicon), diamond or AlN.

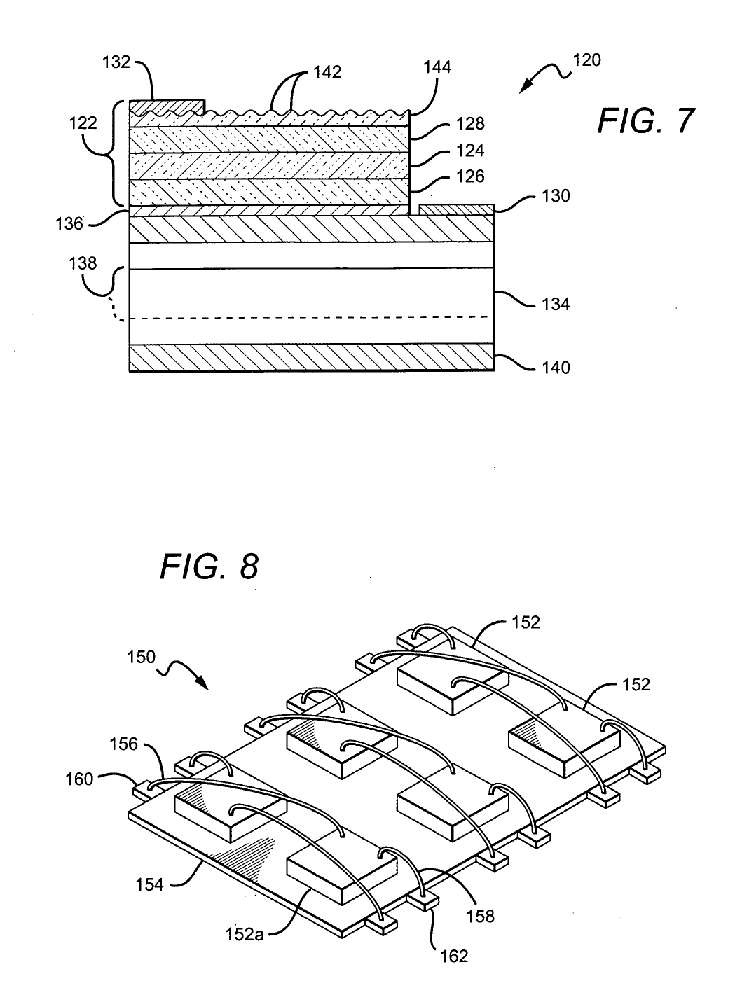

LED chips according to the present invention can also be fabricated with other features to enhance light extraction and to improve emission efficiency. FIG. 7 shows another embodiment of an LED chip 120 according to the present invention comprising an LED 122 with an active region 124 sandwiched between first and second oppositely doped layer 126, 128, with the first layer 126 in electrical contact with a first bond pad 130, and the second layer in electrical contact with a second bond pad 132.

The LED 122 is on a substrate 134 with a p-type/reflector layer 136 between the two. The LED 122 further comprises a topside electrically insulating layer 138, although it is understood that the layer 138 can be in other locations, such as on the backside of the substrate 134. The LED chip further comprises an electrically neutral mounting pad 140. To enhance light extraction, the LED chip 120 further comprises light extraction elements on the top surface of the second doped layer 128. Different light extraction elements can be included such as surface roughening, etches or cuts, with the preferred light extraction elements comprising surface micro-lenses 142. The micro-lenses can be formed using known techniques and can either be formed in the top second oppositely doped layer 128. Alternatively, and as shown, a lens layer 144 can be formed on the second oppositely doped layer 128 and the micro lenses 142 can be formed in the lens layer 144. The lens layer 144 can be made of many different materials, but is preferably made of a material with a similar index of refraction to the second oppositely doped layer to reduce TIR at the interface between the second oppositely doped layer 128 and the lens layer 144.

As discussed above, LED chips according to the present invention can be mounted in an array for SSL applications. FIG. 8 shows one embodiment of an SSL device 150 according to the present invention having an array of LED chips 152 that are preferably mounted to a circuit board. In some embodiments the circuit board can be metal core or can have thermal vias. Each of the LED chips 152 have a thermally conductive substrate and an electrically neutral solderable backside metal, and each of the LEDs 152 is soldered in place by its mounting pad. This combination of thermally conductive substrate and electrically neutral backside metal provide certain advantages. The LED chips 152 can operate at elevated temperatures and heat from the LED chips 152 conducts through the substrate and to the circuit board 154 where it can dissipate in the ambient air or through a heat sink. The electrically neutral bond pads allow each of the LED chips to be controlled individually through respective conductors attached to the bond pads on each of the LEDs. In the embodiment shown, each of the LED chips 152 has its own first and second wires 156, 158. For example, in LED chip 152a the first wire 156 is coupled between the first bond pad on the LED chip 152a and first contact point 160. The second wire 158 coupled between the second bond pad on the LD chip 152a and second contact point 162. A bias (signal) applied across the first and second contact points 160, 162 is applied to the LED and depending on level of the bias, the LED chip will emit at different levels of luminous flux. Each of the LED chips can be individually controlled by their respective first and second wires.

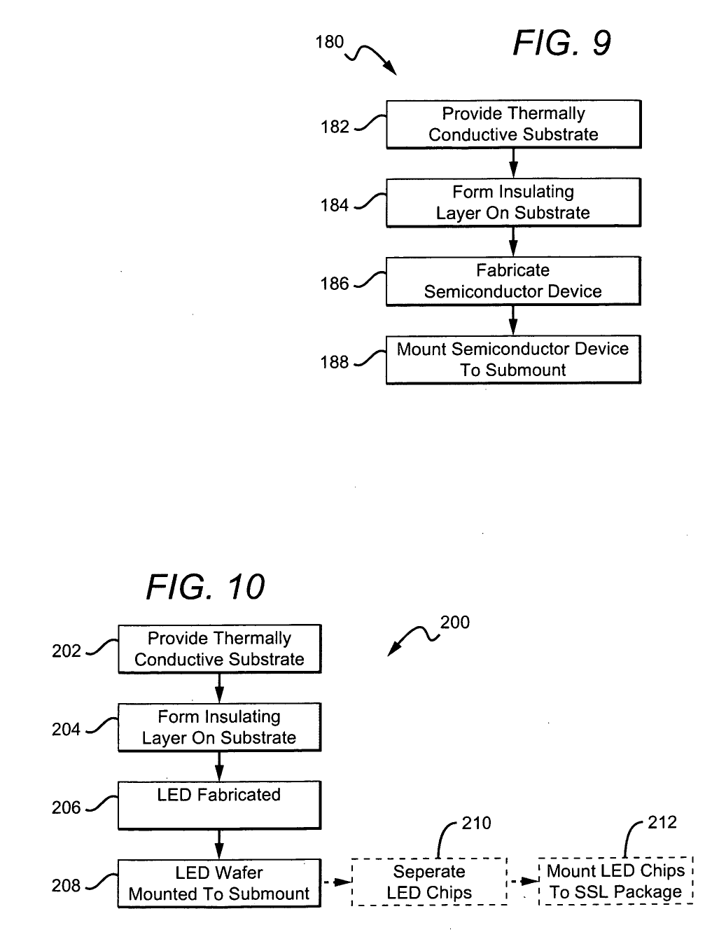

The present invention also comprises methods for fabricating semiconductor devices, and particular LEDs, with electrically neutral mounting pads and thermally conductive substrates. FIG. 9 shows one embodiment of a method 180 according to the present invention, and although the methods herein and the method below are described as a series of steps, it is understood that the steps can take place in different order and can comprise additional or fewer steps. In step 182 a thermally conductive substrate is provided that can be made of the material for the substrates shown in FIGS. 1-7 and described above. In step 184, an electrical insulating layer is formed integral to the substrate, and is preferably formed on the topside or backside surface of the substrate. The insulating layer can comprise materials for the insulating layer shown in FIGS. 1-7 and described above. In this step, the mounting pad can also be formed on the substrate. In step 186, a semiconductor device is fabricated having a plurality of semiconductor layers; In step 188, the semiconductor device is mounted to the substrate with a thermally conductive path from the semiconductor device through the substrate. The insulating layer also provides for the substrate to be electrically neutral while not substantially interfering with the thermal path from the device through the substrate.

FIG. 10 shows one embodiment of a method 200 for fabricating an LED chip according to the present invention. In step 202 a thermally conductive substrate is provided, and with the substrate being either a single LED chip substrate or a substrate as part of a wafer having a plurality of substrates. In step 204, an insulating layer is formed integral to the substrate, and a mounting pad can also be formed on the substrate. In step 206 an LED is fabricated, and like the substrate, the LED can be formed as a separate device or as part of a wafer having a plurality of LEDs. In step 208, the LED is wafer mounted to the substrate, and in the case where both the LED and substrate are part of a wafer, the LED wafer is wafer mounted to the substrate wafer. Step 210 is optional and utilized in embodiments where the LED and substrate are part of a wafer. In this step the individual LEDs chips can be separated into individual devices. In step 212, the individual LED chips are mounted to in an SSL package, circuit board or heat sink.

Although the present invention has been described in detail with reference to certain preferred configurations thereof, other versions are possible. Therefore, the spirit and scope of the invention should not be limited to the versions described above.

1. A light emitting diode chip, comprising:
a thermally conductive substrate;
a light emitting diode on said substrate with said substrate providing a thermal path to draw heat away from said light emitting diode;
a mounting pad on said substrate; and
an electrical insulating layer integral to said LED chip, said insulating layer for electrically insulating said mounting pad from said light emitting diode and having a thickness for allowing a thermally conductive path from said light emitting diode to said mounting pad.

2. (canceled)

3. The light emitting chip of claim 1, wherein said insulating layer is between said light emitting diode and said substrate.

4. The light emitting chip of claim 1, wherein said insulating layer is between said substrate and said mounting pad.

5. The light emitting diode chip of claim 1, wherein said insulating layer comprises a dielectric material.

6. The light emitting diode chip of claim 5, wherein said insulating layer has a thickness in the range of approximately 0.1 to 5 micrometers.

7. The light emitting diode chip of claim 1, wherein said insulating layer does not substantially interfere with said substrate thermal path.

8. The light emitting diode chip of claim 1, wherein said substrate comprises silicon (Si) or silicon carbide (SiC).

9. The light emitting diode of claim 1, wherein said substrate comprises a thermally conductive dielectric substrate.

10. A light emitting diode chip, comprising:
a light emitting diode;
a semiconductor substrate, said light emitting diode on said substrate, said substrate providing a thermal path from said light emitting diode through said substrate;
a mounting pad on said substrate; and
an electrically insulating layer integral to said substrate, said insulating layer electrically insulating said mounting pad from said light emitting diode, said electrically insulating layer between said thermally conductive substrate and said mounting pad.

11. The light emitting chip of claim 10, further comprising a p-type metal layer between said light emitting diode and said thermally conductive substrate.

12. The light emitting chip of claim 11, further comprising a wafer bonding layer between said p-type metal layer and said thermally conductive substrate.

13. The light emitting diode chip of claim 10, wherein said insulating layer comprises a dielectric material.

14. The light emitting diode chip of claim 10, wherein said insulating layer is in the range of 0.1 to 5 micrometers thick.

15. The light emitting diode chip of claim 10, wherein said insulating layer does not substantially interfere with said substrate thermal path.

16. A semiconductor device chip, comprising:
a semiconductor device comprising a plurality of semiconductor layers;
a semiconductor substrate, said device on said substrate, said substrate providing a thermal path from said device through said substrate;
a mounting pad on said substrate for mounting said substrate; and
an electrically insulating layer integral to said substrate, said insulating layer electrically insulating said mounting pad from said device and having a thickness for allowing for a thermally conductive path from said semiconductor path and to said mounting pad.

17. The device chip of claim 16, wherein said insulating layer is between said device and said substrate.

18. The device chip of claim 16, wherein said insulating layer is between said substrate and said mounting pad.

19. The device chip of claim 16, wherein said insulating layer does not substantially interfere with said substrate thermal path.

20. A solid state light, comprising:
a light emitting diode chip comprising:
a thermally conductive substrate;
a light emitting diode mounted on said substrate with said substrate providing a thermal path to draw heat away from said light emitting diode; and
a mounting pad on said substrate for mounting said light emitting diode, said mounting pad electrically insulated from said light emitting diode through said substrate;
a circuit board, said light emitting diode chip mounted to said circuit board by said mounting pad; and
a p-type metal layer between said substrate and said light emitting diode, said p-type metal layer on less than all of a substrate surface.

21. The solid state light of claim 20, wherein further comprising a heat sink thermally connected to said circuit board.

22. The solid state light of claim 20, further comprising additional light emitting diode chips, each mounted to said circuit board to form an LED chip array.

23. The solid state light of claim 22, further comprising conductors, each of said LEDs having respective conductors to apply respective biases to said LEDs.

24. The solid state light of claim 1, further comprising an electrical insulating layer integral to said LED chip, said insulating layer electrically insulating said mounting pad from said light emitting diode.

25. The solid state light of claim 24, wherein said insulating layer is between said light emitting diode and said mounting pad.

26. The solid state light of claim 24, wherein said insulating layer does not substantially interfere with said substrate thermal path.

27. A method for forming a semiconductor device chip, comprising:
providing a thermally conductive substrate;
forming an electrical insulating layer integral to said substrate;
forming a mounting pad on said substrate;
fabricating a semiconductor device having a plurality of semiconductor layers; and
mounting said semiconductor device to said substrate with said substrate providing a thermal path from said semiconductor device through said substrate, with said insulating layer electrically formed to insulate said semiconductor device from said mounting pad.

28. A method for fabricating an light emitting diode chip, comprising:
providing a thermally conductive substrate;
forming an electrical insulating layer integral to said substrate;
forming a mounting pad on said substrate;
fabricating a light emitting diode;
mounting said light emitting diode to said substrate and with said light emitting diode electrically insulated from said mounting pad by said electrically insulating layer.

29. The method of claim 28, wherein said substrate provides a thermal path from said semiconductor through said substrate.

30. The method of claim 28, wherein said mounting step comprises wafer mounting.

31. The method of claim 28, wherein each of said light emitting diode and said substrate is part of a wafer, said method further comprising separating said light emitting diode chip from the remainder of said wafers.

32. The method of claim 28, comprising the further step of mounting said light emitting diode in a solid state light.

33. A light emitting diode chip, comprising:
a solderable mounting pad;
a thermally conductive carrier substrate on said mounting pad;
an electrically insulating layer on said carrier substrate opposite said mounting pad, said insulating layer having a thickness chosen such that heat can transfer readily through said insulating layer;
a p-type semiconductor layer on said insulating layer;
an n-type semiconductor layer on said p-type layer;
an active region interposed between said n-type and p-type layers;
an n-contact pad electrically contacting said n-type layer opposite said carrier substrate; and
a p-contact pad electrically contacting said p-type layer opposite said carrier substrate.

34. The light emitting diode chip of claim 33, wherein said insulating layer comprises a dielectric material.

35. The light emitting diode chip of claim 33, wherein said insulating layer has a thickness in the range of approximately 0.1 to 5 micrometers.

36. The light emitting diode of claim 33, wherein said carrier substrate comprises a thermally conductive dielectric substrate.

37. The light emitting diode of claim 33, wherein said n-type and p-type layers comprise Group III nitride materials.
